(19) United States
(12) Patent Application Publication
(10) Pub. No.: US 2025/0157814 A1
(43) Pub. Date: May 15, 2025

(54) METHOD FOR DEPOSITING BORON CONTAINING SILICON GERMANIUIM LAYERS

(71) Applicant: ASM IP Holding B.V., Almere (NL)

(72) Inventors: Lucas Petersen Barbosa Lima, Heverlee (BE); Rami Khazaka, Leuven (BE); Qi Xie, Wilsele (BE)

(21) Appl. No.: 19/021,548

(22) Filed: Jan. 15, 2025

Related U.S. Application Data
(63) Continuation of application No. 17/345,458, filed on Jun. 11, 2021, now Pat. No. 12,266,524.
(60) Provisional application No. 63/039,877, filed on Jun. 16, 2020.
(60) Provisional application No. 63/070,519, filed on Aug. 26, 2020.

(51) Int. Cl. H01L 21/02; C30B 25/04; C30B 25/16; C30B 25/18; C30B 29/52; C30B 33/12; H10D 62/834

(52) U.S. Cl. CPC H01L 21/02579; C30B 25/04; C30B 25/165; C30B 25/18; C30B 29/52; C30B 33/12; H01L 21/02532; H01L 21/0262; H10D 62/834

(57) ABSTRACT

Methods and devices for epitaxially growing boron doped silicon germanium layers. The layers may be used, for example, as a p-type source and/or drain regions in field effect transistors.

### CROSS-REFERENCE TO RELATED APPLICATIONS

This application is a continuation of, and claims priority to, U.S. patent application Ser. No. 17/345,458 filed Jun. 11, 2021, titled METHOD FOR DEPOSITING BORON CONTAINING SILICON GERMANIUM LAYERS; which claims priority to U.S. Provisional Patent Application Ser. No. 63/039,877 filed Jun. 16, 2020 titled METHOD FOR DEPOSITING BORON CONTAINING SILICON GERMANIUM LAYERS, and U.S. Provisional Patent Application Ser. No. 63/070,519 filed Aug. 26, 2020 titled METHOD FOR DEPOSITING BORON CONTAINING SILICON GERMANIUM LAYERS, the disclosures of which are hereby incorporated by reference in their entirety.

### FIELD OF INVENTION

The present disclosure generally relates to methods and systems suitable for forming electronic devices. More particularly, the disclosure relates to methods and systems that can be used for depositing material, for example, for selectively depositing material, such as doped semiconductor material, on a surface of a substrate.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

One particular challenge relates to the manufacture of defect-free active regions of a semiconductor device structure. Examples of such active regions are source, drain, and channel regions in field effect transistors, e.g., FinFETs, gate all around transistors, and the like. Furthermore, in many applications, it may be desirable to selectively deposit semiconductor material (e.g., Group IV semiconductor material) that incorporates a dopant. However, such techniques may not be well developed. Accordingly, improved methods and systems for depositing doped semiconductor material are desired.

In addition, there is a particular need for depositing semiconductor material at ever lower temperatures because the thermal budget that many advanced electronic devices can withstand is limited.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to deposition methods, e.g., selective or non-selective deposition methods, to structures and devices formed using such methods, and to apparatus for performing the methods and/or for forming the structure and/or devices. While the ways in which various embodiments of the present disclosure address drawbacks of prior methods and systems are discussed in more detail below, in general, various embodiments of the disclosure provide improved methods of selectively depositing doped semiconductor layers. The doped semiconductor layers may be suitable as source, drain, and/or channel regions in field effect transistors such as FinFETs and gate all around metal oxide semiconductor field effect transistors.

In particular, described herein is a method for epitaxially growing a boron doped silicon germanium layer. The method comprises the provision of a substrate comprising a monocrystalline surface in a reactor chamber and introducing a silicon precursor, a germanium precursor, a boron precursor, and a carrier gas into the reactor chamber, thereby epitaxially growing a boron doped silicon germanium layer on the monocrystalline surface. Suitably, the silicon precursor comprises disilane (Si₂H₆), the germanium precursor comprises germane (GeH₄), and the boron precursor comprises diborane (B₂H₆).

In some embodiments, the carrier gas essentially consists of one or more inert gasses.

In some embodiments, the carrier gas is selected from the list consisting of N₂, He, Ne, Kr, Ar, and Xe.

In some embodiments, the carrier gas consists of N₂.

In some embodiments, the substrate is maintained at a temperature of at least 300° C. to at most 450° C.

In some embodiments, the substrate is maintained at a temperature of at least 350°° C. to at most 420° C.

In some embodiments, the reactor chamber is maintained at a pressure of at least 10 Torr to at most 160 Torr.

In some embodiments, the carrier gas is provided to the reactor chamber at a flow rate of at least 2 slm to at most 30 slm.

In some embodiments, the silicon precursor is provided to the reactor chamber at a flow rate of at least 15 to at most 45 sccm.

In some embodiments, the germanium precursor is provided to the reactor chamber at a flow rate of at least 350 to at most 2000 sccm.

In some embodiments, the boron precursor is provided to the reactor chamber at a flow rate of at least 0.5 sccm to at most 60 sccm.

In some embodiments, the method further comprises introducing a gallium precursor into the reactor chamber, thereby epitaxially growing a boron and gallium doped silicon germanium layer on the monocrystalline surface.

In some embodiments, the substrate comprises a first surface and a second surface. The first surface is a monocrystalline surface. The second surface is a dielectric surface. The boron doped silicon germanium layer is then selectively and epitaxially grown on the first surface.

In some embodiments, parasitic boron doped silicon germanium is grown on the second surface and the method further comprises the step of: introducing an etch gas into the reactor chamber, thereby etching the parasitic boron doped silicon germanium grown on the second surface. In some embodiments, the parasitic boron doped silicon germanium comprises parasitic boron doped silicon germanium nuclei and/or amorphous silicon germanium. Thus, in some embodiments, parasitic boron doped silicon germanium nuclei are grown on the second surface and the method further comprising the step of introducing an etch gas into the reactor chamber, thereby etching the parasitic nuclei on the second surface.

In some embodiments, the steps of introducing the silicon precursor, the germanium precursor, the boron precursor, and the carrier gas into the reactor chamber; and, introducing an etch gas into the reactor chamber; are repeated until the boron doped epitaxial silicon germanium layer on the first surface has reached a pre-determined thickness.

In some embodiments, the etch gas comprises a halogen.

In some embodiments, the etch gas is selected from the list consisting of HCl, Cl₂, and HBr. In some embodiments, the etch gas comprises HCl.

In some embodiments, the second surface is selected from the list consisting of a silicon oxide surface, a silicon nitride surface, a silicon oxycarbide surface, a silicon oxynitride surface, a hafnium oxide surface, a zirconium oxide surface, and an aluminum oxide surface.

In some embodiments, the silicon precursor is disilane, the germanium precursor is germane, and the boron precursor is diborane.

In some embodiments, the monocrystalline surface comprises a monocrystalline silicon surface.

In some embodiments, the monocrystalline surface comprises a monocrystalline silicon germanium surface.

In some embodiments, the monocrystalline silicon germanium surface comprises a boron doped silicon germanium surface.

Further described is a system that comprises one or more reaction chambers, a gas injection system, and a controller configured for causing the system to perform a method as described herein.

Further described is a field effect transistor comprising a boron doped silicon germanium layer as a source, drain, or channel. The boron doped silicon germanium layer is deposited by means of a method as described herein.

In accordance with yet additional examples of the disclosure, a system to perform a method as described herein and/or to form a structure, device, or portion of either is disclosed.

These and other embodiments will become readily apparent to those skilled in the art from the following detailed description of certain embodiments having reference to the attached figures. The invention is not being limited to any particular embodiments disclosed.

### BRIEF DESCRIPTION OF THE FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a substrate (200) on which boron doped silicon germanium layer may be deposited in accordance with exemplary embodiments of the disclosure.

FIG. 3 illustrates a system (300) in accordance with additional exemplary embodiments of the disclosure.

FIG. 4 shows XRD (X-Ray Diffraction) and XRR (X-Ray Reflectivity) measurements on a boron doped silicon germanium layer grown using the methods described herein.

FIG. 5 shows transmission electron microscopy images of an intermediate structure that may be encountered during an exemplary embodiment of a method as described herein.

Throughout the drawings, the following numbering is used: 100—method; 102—substrate providing step; 104—deposition step; 108—etching step; 110—cyclic loop/repetition of deposition step 104 and etching step 108; 112—method end; 200—substrate; 202—monocrystalline material; 204—non-monocrystalline material; 206—first area; 208—second area; 210—monocrystalline surface; 212—non-monocrystalline surface; 300—system; 302—substrate handling system; 304—reaction chamber; 306—injection system; 308—wall; 310—first gas source; 311—second gas source; 312—third gas source; 314—fourth gas source; 316—fifth gas source; 318—line; 320—line; 322—line; 324—line; 326—exhaust; 328—controller; 330—pyrometer; 510—monocrystalline silicon; 520—silicon oxide layer; 530—silicon nitride layer; 540—epitaxial and monocrystalline boron-doped silicon germanium; 545—amorphous boron-doped silicon germanium.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for depositing boron doped silicon germanium on a surface of a substrate. Exemplary methods can be used to, for example, form source and/or drain regions of semiconductor devices that exhibit relatively high mobility, relatively low contact resistance, and that maintain the structure and composition of the deposited layers. For example, the layers can be used as p-type source and/or drain regions in p-channel MOSFETS. Exemplary MOSFETS in which these layers can be used include FinFETs and GAA (Gate-All-Around) FETS. In addition, the present methods can be used to form low-defect channel regions in n-channel MOSFETS. In addition, the present layers are especially useful for the formation of shallow junctions because of a reduced channeling effect. In some embodiments, the present methods involve selectively depositing boron doped silicon germanium.

As used herein, the term “gate all around transistor” may refer to devices which include a conductive material wrapped around a semiconductor channel region. As used herein, the term “gate all around transistor” may also refer to a variety of device architectures such as nanosheet devices, forksheet devices, vertical FETs, etc.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a noble gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed. As set forth in more detail below, a surface of a substrate can include two or more areas, wherein each of the two or more areas comprise different material.

As used herein, the term “epitaxial layer” can refer to a substantially single crystalline layer upon an underlying substantially single crystalline substrate or layer, the two substantially single crystalline layers having a substantially identical crystal orientation.

As used herein, the term “chemical vapor deposition” can refer to any process wherein a substrate is exposed to one or more volatile precursors, which react and/or decompose on a substrate surface to produce a desired deposition.

As used herein, the term “film” and/or “layer” can refer to any continuous or non-continuous structures and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. Alternatively, a film or layer may consist entirely of isolated islands.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. It shall be understood that when a composition, method, device, etc. is said to comprise certain features, it means that it includes those features, and that it does not necessarily excludes the presence of other features, as long as they do not render the claim unworkable. This notwithstanding, the wording “comprises” includes the meaning of “consists of”, i.e., the case when the composition, method, device, etc. in question only includes the features, components, and/or steps that are listed, and does not contain any other features, components, steps, etc.

In this disclosure, any defined meanings do not necessarily exclude ordinary and customary meanings in some embodiments.

The term “carrier gas” as used herein may refer to a gas that is provided to a reactor chamber together with one or more precursors. For example, a carrier gas may be provided to the reactor chamber together with one or more of the precursors used herein. Exemplary carrier gasses include N₂, and noble gasses such as He, Ne, Kr, Ar, and Xe.

As opposed to a carrier gas, a purge gas may be provided to a reactor chamber separately, i.e., not together with one or more precursors. This notwithstanding, gasses which are commonly used as carrier gas may also be used as a purge gas, even within the same process. For example, in a cyclic deposition-etch process, N₂ used as a carrier gas may be provided together with one or more precursors during deposition pulses, and N₂ used as a purge gas may be used to separate deposition and etch pulses. Of course, N₂ may be replaced by another suitable inert gas such as a noble gas such as He, Ne, Kr, Ar, and Xe. Hence, it is the manner of how a gas is provided to the reactor chamber that determines whether it serves as a purge gas or a carrier gas in a specific context. Thus, as used herein, the term “purge” may refer to a procedure in which an inert or substantially inert gas is provided to a reactor chamber in between two pulses of gasses which react with each other. For example, a purge, e.g., using nitrogen gas, may be provided between a precursor pulse and an etchant pulse, thus avoiding or at least minimizing gas phase interactions between the precursor and the etchant. It shall be understood that a purge can be effected either in time or in space, or both. For example, in the case of temporal purges, a purge step can be used, e.g., in the temporal sequence of providing a first precursor to a reactor chamber, providing a purge gas to the reactor chamber, and providing an etchant to the reactor chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

Note that the terms “etch pulse” and “etch cycle” can signify an etch step, and can be used interchangeably. Similarly, the terms “deposition pulse” and “deposition cycle” can signify a deposition step, and can be used interchangeably.

As set forth in more detail below, various steps of exemplary methods described herein can be performed in the same reaction chamber or in different reaction chambers of, for example, the same cluster tool.

Thus described herein is a method for epitaxially growing a boron doped silicon germanium layer. The method comprises the provision of a substrate in a reactor chamber. The substrate comprises a monocrystalline surface. In other words, the substrate comprises a monocrystalline material which is exposed at a surface of the substrate. Advantageously, the substrate comprises a monocrystalline silicon surface. Additionally or alternatively, the substrate may comprise a monocrystalline silicon germanium surface. Additionally or alternatively, the substrate may comprise a boron doped silicon germanium surface.

After the substrate has been introduced into the reaction chamber, a silicon precursor, a germanium precursor, and a boron precursor are introduced into the reactor chamber. Thus, a boron doped silicon germanium layer is grown on the monocrystalline surface. It shall be understood that the silicon precursor comprises disilane, the germanium precursor comprises germane, and the boron precursor comprises diborane.

In some embodiments, the boron precursor, the silicon precursor, and the germanium precursor are continually provided to the reaction chamber. Alternatively, the layer may be formed by means of a cyclical deposition process. Thus in some embodiments, the boron precursor, the silicon precursor, and the germanium precursor are sequentially provided to the reactor chamber. Alternatively, any two precursors selected from the boron precursor, the silicon precursor, and the germanium precursor may be simultaneously provided to the reaction chamber in a combined precursor pulse, whereas the boron precursor may be provided to the reactor chamber in separate precursors. In some embodiments, one or more precursors are provided continually to the reactor chamber, and the remaining precursors are provided to the reactor chamber in pulses. Optionally, any or all of the above-mentioned precursor pulses are separated by purge steps. During a purge step precursor flow may be stopped, and a purge gas may be provided to the reaction chamber.

It shall be understood that the present methods may be carried out after any suitable pre-clean. One possible pre-clean is a gas-phase pre-clean, e.g., a plasma clean that results in an H-terminated silicon surface. Another possible pre-clean uses wet chemistry. For example, the following sequence may be used: surface oxidation in a mixture consisting of NH₄OH, H₂O₂, and H₂O; followed by a rinse; followed by an HF dip; followed by a rinse. A suitable HF dip comprises, for example, a dip in a mixture consisting of from at least 0.1 vol. % to at most 1.5 vol. % HF in water, e.g., distilled or deionized water. Additionally or alternatively, a gas-phase pre-clean may be used.

In some embodiments, the method further comprises introducing a carrier gas into the reactor chamber. This can be particularly useful when, for example, hard to volatilize precursors are used, in which case a carrier gas can help with bringing the precursors to the reaction chamber. For example, a boron precursor such as diborane may be provided to the reaction chamber aided by a carrier gas. For example, a silicon precursor such as silane may be provided to the reaction chamber aided by a carrier gas. For example, a germanium precursor such as germane may be provided to the reaction chamber aided by a carrier gas. For example, a gallium precursor such as triethylgallium or tri-tert-butylgallium may be provided to the reaction chamber aided by a carrier gas. For example, an etch gas such as HCl, Cl₂, or HBr may be provided to the reaction chamber aided by a carrier gas. In some embodiments, the carrier gas essentially consists of one or more inert gasses. In some embodiments, the carrier gas is selected from the list consisting of noble gasses and nitrogen. In some embodiments, the carrier gas is selected from the list consisting of N₂, He, Ne, Kr, Ar, and Xe. In some embodiments, the carrier gas essentially consists of N₂. In some embodiments, the carrier gas consists of N₂. In some embodiments, the noble gas comprises helium. In some embodiments, the noble gas comprises krypton. In some embodiments, the noble gas comprises neon. In some embodiments, the noble gas comprises argon. In some embodiments, the noble gas comprises xenon. In some embodiments, N₂ is used as a carrier gas. In some embodiments, the carrier gas is provided to the reactor chamber at a flow rate from at least 1.0 slm to at most 100 slm, or from at least 2.0 slm to at most 30 slm, or from at least 2.0 slm to at most 50 slm, or from at least 5.0 slm to at most 20.0 slm, or from at least 8.0 slm to at most 12.0 slm.

In some embodiments, the carrier gas is provided to the reactor chamber at a flow rate of at least 2.0 slm to at most 30 slm, or of at least 5 slm to at most 20 slm (standard liters per minute).

In some embodiments, the silicon precursor is provided to the reactor chamber at a flow rate of at least 5 to at most 600 sccm. In some embodiments, the silicon precursor is provided to the reactor chamber at a flow rate of at least 15 to at most 45 sccm (standard cubic centimeters per minute).

In some embodiments, the germanium precursor is provided to the reactor chamber at a flow rate of at least 800 to at most 3200 sccm. In some embodiments, the germanium precursor is provided to the reactor chamber at a flow rate of at least 350 to at most 3200 sccm. In some embodiments, the germanium precursor is provided to the reactor chamber at a flow rate of at least 50 to at most 3200 sccm. In some embodiments, the germanium precursor is provided to the reactor chamber at a flow rate of at least 50 to at most 3200 sccm. In some embodiments, the germanium precursor is provided to the reactor chamber at a flow rate of at least 800 to at most 2000 sccm. In some embodiments, the germanium precursor is provided to the reactor chamber at a flow rate of at least 350 to at most 2000 sccm.

In some embodiments, the boron precursor is provided to the reactor chamber at a flow rate of at least 1 sccm to at most 50 sccm. In some embodiments, the boron precursor is provided to the reactor chamber at a flow rate of at least 0.5 sccm to at most 120 sccm. In some embodiments, the boron precursor is provided to the reactor chamber at a flow rate of at least 0.5 sccm to at most 60 sccm. In some embodiments, the boron precursor is provided to the reactor chamber at a flow rate of at least 1.0 sccm to at most 60 sccm. In some embodiments, the boron precursor is provided to the reactor chamber at a flow rate of at least 1.0 sccm to at most 40 sccm. In some embodiments, the boron precursor is provided to the reactor chamber at a flow rate of at least 5 sccm to at most 20 sccm. In some embodiments, the boron precursor is provided to the reactor chamber at a flow rate of at least 5 sccm to at most 30 sccm. In some embodiments, the boron precursor is provided to the reactor chamber at a flow rate of at least 5 sccm to at most 45 sccm. In some embodiments, the boron precursor is provided to the reactor chamber at a flow rate of at least 10 sccm to at most 50 sccm.

In some embodiments, the method further comprises introducing a gallium precursor into the reactor chamber. Thus a boron and gallium doped silicon germanium layer may be epitaxially grown on the monocrystalline surface.

In some embodiments, the gallium precursor is a gallium alkyl. In some embodiments, the gallium precursor is a gallium halide. In some embodiments, the gallium precursor is selected from the list consisting of trimethylgallium, triethylgallium, tritertiarybutylgallium, Ga(BH₄)₃, GaH₃, and diethylgallium chloride. In some embodiments, the gallium precursor is triethylgallium (CH₃CH₂)₃Ga. The gallium precursor may be provided to the reactor chamber pure, i.e., at a concentration of 100 vol. %. Alternatively, the gallium precursor may be provided in a diluted form with a carrier gas.

The present methods may allow for intrinsic selective growth of boron doped silicon germanium layers within a pre-determined selectivity window. In other words, the present methods may be used to selectively grow boron doped silicon germanium on one part of a substrate (e.g., a monocrystalline silicon surface), whereas no, or no substantial amount of, growth occurs on another part of that substrate (e.g., a silicon oxide surface). As used herein, the term “selectivity window” may refer to a thickness range of a grown layer in which the layer can be grown solely, or substantially solely, on one part of a substrate and not on one or more other parts of the substrate. Exemplary selectivity windows are 20 nm, 10 nm, 8 nm, 6 nm, 5 nm, 4 nm, 3 nm, 2 nm, and 1 nm. Thus, in some embodiments, the substrate comprises a first surface and a second surface. The first surface is a monocrystalline surface, and the second surface is a dielectric surface. In these methods, the boron doped silicon germanium layer is selectively and epitaxially grown on the first surface.

In one embodiment that enables selective growth, the substrate comprises a first surface and a second surface. The first surface is a monocrystalline surface, e.g., a monocrystalline silicon surface or a monocrystalline silicon germanium surface. Additionally or alternatively, the substrate may comprise a monocrystalline silicon germanium surface. Additionally or alternatively, the substrate may comprise a boron doped silicon germanium surface. The first surface preferably has a hydrogen termination. The first surface may be a surface of a doped layer, e.g., a boron-doped silicon layer. Alternatively, the first surface may be a surface of an undoped layer. The second surface is a dielectric surface, and the boron doped silicon germanium layer is selectively and epitaxially grown on the first surface. In other words, the boron doped silicon germanium layer is grown on the first surface and not, or not substantially, on the second surface. Without the invention being limited by any theory or mode of operation, it shall be understood that such selectivity may be obtained through nucleation delay on the second surface compared to the first surface.

In some embodiments, the second surface is selected from the list consisting of a silicon oxide surface, a silicon nitride surface, a silicon oxycarbide surface, a silicon oxynitride surface, a hafnium oxide surface, a zirconium oxide surface, and an aluminum oxide surface. In some embodiments, material exposed on the second surface can include, for example, a dielectric material, such as an oxide, a nitride, an oxynitride, an oxycarbide, an oxycarbide nitride, and/or the like, such as silicon nitride, silicon oxide (SiO₂), silicon carbide and mixtures thereof, such as SiOC, SiOCN, SiON. In some embodiments, the second area has a silicon oxide surface. In other words, in some embodiments, the second material consists of silicon oxide (SiO₂).

In some embodiments that enable selective growth, an etchant is provided to the reaction chamber while the silicon, germanium, and boron precursors are provided to the reaction chamber. Such an approach may enhance selectivity. Suitable etch gasses include halogen-containing compounds. Exemplary halogens include fluorine, chlorine, bromine, and iodine. In some embodiments, the etch gas comprises chlorine. Exemplary chlorine containing etch gasses include HCl and Cl₂. An exemplary bromine containing etch gas includes HBr.

In some embodiments, parasitic boron doped silicon germanium is grown on the second surface and the method further comprises the step of: introducing an etch gas into the reactor chamber, thereby etching the parasitic boron doped silicon germanium grown on the second surface. In some embodiments, the parasitic boron doped silicon germanium comprises parasitic boron doped silicon germanium nuclei and/or amorphous silicon germanium. Thus, in some embodiments, parasitic boron doped silicon germanium nuclei are grown on the second surface during selective growth. In such a case, the present methods suitably comprise a step of introducing an etch gas into the reactor chamber, thereby etching the parasitic nuclei and/or the amorphous silicon germanium on the second surface.

In some embodiments, the following steps are repeated until the boron doped epitaxial silicon germanium layer on the first surface has reached a pre-determined thickness: introducing the silicon precursor, the germanium precursor, the boron precursor, and the carrier gas into the reactor chamber; and, introducing an etch gas into the reactor chamber. In particular, these steps may be repeated until the boron doped epitaxial silicon germanium layer on the first surface has reached a pre-determined thickness.

When it is desirable to selectively grow a boron doped silicon germanium layer having a thickness that is higher than the selectivity window, a deposition-etch approach may be used. This may be done, for example, by first growing a boron doped silicon germanium layer as described herein, and then introducing an etch gas into the reactor chamber, thereby etching the boron doped silicon germanium layer. Suitable etch gasses include halogen-containing compounds. Exemplary halogens include fluorine, chlorine, bromine, and iodine. In some embodiments, the etch gas comprises chlorine. Exemplary chlorine containing etch gasses include HCl and Cl₂. An exemplary bromine containing etch gas includes HBr.

Without the invention being limited by any theory or particular mode of operation, it is believed that during epitaxial growth of boron doped silicon germanium on the first surface, parasitic boron doped silicon germanium, such as amorphous boron doped silicon germanium and/or parasitic nuclei of boron doped silicon germanium, may be formed on the second surface as well. Introducing the etch gas into the reactor chamber, completely or substantially completely etches the parasitic boron doped silicon germanium, such as amorphous boron doped silicon germanium and/or boron-doped silicon germanium nuclei, in the second area while etching only part of the epitaxial boron doped silicon germanium layer in the first area.

In some embodiments, the step of depositing the boron doped silicon germanium layer and the etch step are separated by a purge step.

The aforementioned deposition-etch approach may be repeated in order to epitaxially grow layers of any desired thickness. Accordingly, in some embodiments, the following steps are repeated until the boron doped epitaxial silicon germanium layer on the first surface has reached a pre-determined thickness: introducing the silicon precursor, the germanium precursor, the boron precursor, and the carrier gas into the reactor chamber; and, introducing an etch gas into the reactor chamber. Optionally, these steps are separated by purge steps.

In other words, in some embodiments, the sequence of the deposition step and etching step are repeated as desired until a pre-determined thickness of the epitaxial boron doped silicon geranium layer is formed overlaying the first area. For example, the deposition step and the etching step can be repeated from at least 1 to at most 1000 times, from at least 2 to at most 100 times, from at least 2 to at most 50 times, from at least 2 to at most 30 times, from at least 2 to at most 20 times, or from at least 5 to at most 15 times, or from at least 8 to at most 12 times.

In other words, selective growth may be achieved by cyclically performing the following sequence of sub steps i. and ii. Step i. comprises epitaxially growing a boron doped silicon germanium layer on the monocrystalline surface and growing a boron doped amorphous and/or polycrystalline silicon germanium layer on the second surface by introducing disilane, germane, diborane, and a carrier gas into the reactor chamber. Step ii. comprises etching the epitaxial boron doped silicon germanium layer on the first surface and etching the amorphous and/or polycrystalline boron doped silicon germanium layer on the second surface by introducing an etchant into the reactor chamber. The sequence of sub steps i. and ii. is then repeated until the epitaxial boron doped silicon germanium layer on the monocrystalline surface has reached a pre-determined thickness. Optionally, steps i and ii may be separated by a purge step.

The etch step (ii) can be performed in the same reaction chamber used during the deposition step (i). Alternatively, the etch step can be performed in another reaction chamber, such as another reaction chamber in the same cluster tool as the reaction chamber used during the deposition step. The temperature and/or pressure which is maintained during the etching step can be the same or similar to the temperature and/or pressure described above in connection with the deposition step.

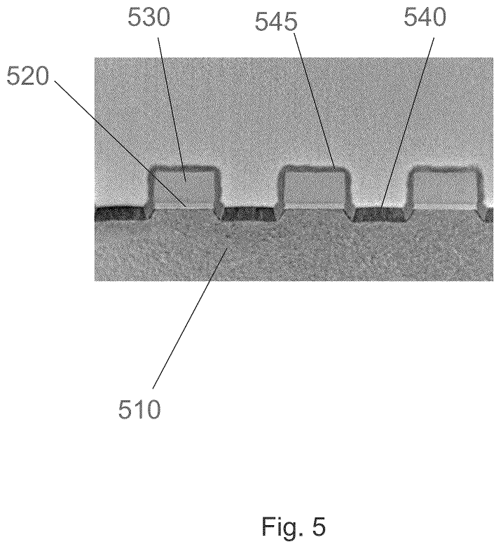

Without the invention being bound by any theory or specific mode of operation, it shall be understood that selectivity may be obtained through any one or a combination of the following mechanisms: 1) amorphous boron doped silicon germanium grows at a slower rate in the second area than epitaxial boron doped silicon germanium in the first area, 2) amorphous boron doped silicon germanium growth on the second surface exhibits delayed growth, i.e., nucleation delay, with respect to epitaxial boron doped silicon germanium in the first area (see, e.g., FIG. 5), and/or 3) amorphous boron doped silicon germanium in the second area is etched at a faster rate than epitaxial boron doped silicon germanium in the first area. Thus, an epitaxial boron doped silicon germanium layer may be grown in the first area whereas no deposition occurs in the second area. In other words, an epitaxial boron doped silicon germanium film is grown on a first surface in the first area whereas after deposition, no or no substantial amount of amorphous boron doped silicon germanium remains on a second surface in the second area. Without the invention being bound by any theory or particular mode of operation, it is believed that nucleation delay (i.e., mechanism 2) plays a major role in obtaining selectivity in the methods that are described herein.

In some embodiments, the etchant comprises an elementary halogen. In some embodiments, the etchant comprises HCl. In some embodiments, the etchant comprises chlorine. In other words, Cl₂ is used in some embodiments as an etchant. In some embodiments, Cl₂ is provided during the etch cycles to the reaction chamber at a flow rate from at least 5.0 sccm to at most 400.0 sccm, or from at least 5.0 sccm to at most 200.0 sccm or from at least 5.0 sccm to at most 100.0 sccm, or from at least 10.0 sccm to at most 50.0 sccm, or from at least 15.0 sccm to at most 40.0 sccm, or from at least 20.0 sccm to at most 30.0 sccm.

In some embodiments, the etch cycles may last from at least 1.0 s to at most 400.0 s, or from at least 2.0 s to at most 200.0 s, or from at least 4.0 s to at most 100.0 s, or from at least 8.0 s to at most 50.0 s, or from at least 10.0 s to at most 40.0 s, or from at least 20.0 s to at most 30.0 s.

In some embodiments, temperature and pressure are kept constant throughout the deposition cycles and the etch cycles, i.e., throughout the boron doped silicon germanium deposition steps and the etch steps.

In some embodiments, etch cycles and deposition cycles can be at different pressures. In other words, in some embodiments, the step of depositing the boron doped silicon germanium layer and the step etching may be at different pressures. Preferably, the aforementioned pressures differ by no more than 10%, or by no more than 20%, or by no more than 50%, or by no more than 100%, or by no more than 200%, or by no more than 500%, or by no more than 1000%, relative to the lowest pressure that occurs. Keeping the pressure differences limited in this way may speed up processing time by limiting the amount of time needed for pumping between the cycles.

In an advantageous embodiment, for example when Cl₂ is used as an etch gas, the pressure during an etch cycle is less than 90 Torr, e.g. from at least 0.5 Torr to at most 90 Torr, or from at least 0.5 Torr to at most 1.0 Torr, or from at least 1.0 Torr to at most 2.0 Torr, or from at least 2.0 Torr to at most 5.0 Torr, or from at least 5.0 Torr to at most 10.0 Torr, or from at least 10.0 Torr to at most 20.0 Torr, or from at least 20.0 Torr to at most 40.0 Torr, or from at least 40.0 Torr to at most 60.0 Torr, or from at least 60.0 Torr to at most 90.0 Torr. Doing so can enhance the safety of some embodiments of the present methods. In some embodiments, the pressure during a deposition cycle is the same as the pressure of an etch cycle. Alternatively, the pressure during a deposition cycle may be different from the pressure used during an etch cycle.

In some embodiments, the deposition cycles and the etch cycles are separated by purges. In some embodiments, an inert gas is used as a purge gas. Suitable purge gasses include nitrogen and the noble gasses. Suitable noble gasses may include He, Ne, Ar, Kr, and Xe. In some embodiments, the purge gas consists of N2. In some embodiments, the purges last from at least 5.0 s to at most 80.0 s, or from at least 10.0 s to at most 40.0 s, or from at least 15.0 to at most 30.0 s, or for about 20.0 s. In some embodiments, the purge gas is provided to the reaction chamber during the purges at a flow rate of at least 5000 to at most 100 000 sccm, or of at least 10 000 to at most 50 000 sccm, or of at least 20000 to at most 30000 sccm.

In some embodiments, the etch gas comprises a halogen.

In some embodiments, the etch gas is selected from the list consisting of HCl, Cl₂, and HBr.

In some embodiments, the second surface is a dielectric surface. In some embodiments, the second surface may contain silicon and one or more species selected from carbon, nitrogen, and oxygen. In some embodiments, the second surface is a surface of an oxide, nitride, or carbide of an element selected from Hf, Zr, La, Al, and mixtures thereof. In some embodiments, the second surface is a metal oxide. In some embodiments, the second surface is a metal nitride. In some embodiments, the second surface is a metal carbide. In some embodiments, the second surface comprises metal nitride, metal oxide, and/or metal carbide bonds. In some embodiments, the second surface is selected from the list consisting of a silicon oxide surface, a silicon nitride surface, a silicon oxycarbide surface, a silicon oxynitride surface, a hafnium oxide surface, a zirconium oxide surface, and an aluminum oxide surface.

In some embodiments, the silicon precursor is disilane, the germanium precursor

is germane, and the boron precursor is diborane.

In some embodiments, whether selective or not, the substrate is maintained at a temperature of at least 200°° C. to at most 450° C. For example, the reactor chamber may be maintained at a temperature of at least 220° C. to at most 440° C., or at a temperature of at least 240°° C. to at most 430° C., or at a temperature of at least 250° C. to at most 420° C., or at a temperature of at least 260° C. to at most 410° C., or at a temperature of at least 280° C. to at most 400° C., or at a temperature of at least 300°° C. to at most 390° C., or at a temperature of at least 290°° C. to at most 380° C., or at a temperature of at least 320° C. to at most 370° C., or at a temperature of at least 340°° C. to at most 360° C. In some embodiments, the substrate is maintained at a temperature of at least 300° C. to at most 450° C. In some embodiments, the substrate is maintained at a temperature of at least 350° C. to at most 420° C., or at a temperature of at least 250° C. to at most 350° C.

In other words, in some embodiments, the substrate is maintained at the aforementioned temperatures during the epitaxial deposition of the boron doped silicon germanium. These temperatures may also be maintained during any etch steps, if present. The temperatures mentioned herein may be suitably measured by means of a pyrometer 330 suspended in the reactor chamber and above the substrate.

It shall be understood that the substrate temperatures measured by a pyrometer suspended in the reaction chamber and above the substrate may differ from substrate temperatures measured by other means, such as substrate temperatures measured by means of a thermocouple in a support, e.g. susceptor, that supports the substrate in the reaction chamber during the methods as described herein. For example, a substrate temperature measured by means of such a thermocouple may be, e.g. from at least 50°° C. to at most 100° C., or from at least 60° C. to at most 90° C., or from at least 70° C. to at most 80° C. lower than the substrate temperature measured by means of a pyrometer 330 suspended in the reaction chamber and above the substrate. For example, a temperature of 400° C. as measured by a pyrometer 330 suspended in the reaction chamber and above the substrate may correspond to a temperature of 320° C. as measured by a support, e.g. susceptor, that supports the substrate in the reaction chamber.

In some embodiments, the reactor chamber is maintained at a pressure of at least 10 Torr to at most 740 Torr. In some embodiments, the reactor chamber is maintained at a pressure of at least 10 Torr to at most 160 Torr. In some embodiments, the reactor chamber is maintained at a pressure of at least 40 Torr to at most 160 Torr. In some embodiments, the reactor chamber is maintained at a pressure of at least 10 Torr to at most 200 Torr, or at a pressure of at least 10 Torr to at most 80 Torr, or at a pressure of at least 80 Torr to at most 180 Torr, or at a pressure of at least 60 Torr to at most 100 Torr, or at a pressure of at least 40 Torr to at most 80 Torr, or at a pressure of at least 80 Torr to at most 115 Torr, or at a pressure of at least 115 Torr to at most 150 Torr. In other words, in some embodiments, the reaction chamber is maintained at the aforementioned pressures during the epitaxial deposition of the boron doped silicon germanium.

The aforementioned pressures may also be maintained during any etch steps, if present. Thus, during a selective process comprising a sequence of deposition cycles (i.e., deposition cycles of boron doped silicon germanium), and etch cycles, the pressure during the etch cycles may be the same as the pressure used during the deposition cycles. This notwithstanding, and in some embodiments, the pressure during the etch cycles may be different than the pressure used during the deposition cycles. In some embodiments, the pressure during the etch cycles equals the pressure during the deposition cycles within a margin of error of 50%, or within a margin of error of 40%, or within a margin of error of 30%, or within a margin of error of 20%, or within a margin of error of 10%, or within a margin of error of 5%.

Further provided is a system comprising one or more reaction chambers, a gas injection system, and a controller. The controller is configured for causing the system to perform a method for epitaxially depositing a boron doped silicon germanium layer as described herein.

In accordance with yet additional embodiments of the disclosure, a device or portion thereof can be formed using a method and/or a structure as described herein. The boron doped silicon germanium layer can be used to form a source, drain, and/or channel region of the device. The device can be, for example, a field effect transistor (FET) (e.g., a FinFET, gate all around transistor, or a stack comprising multiple transistor devices).

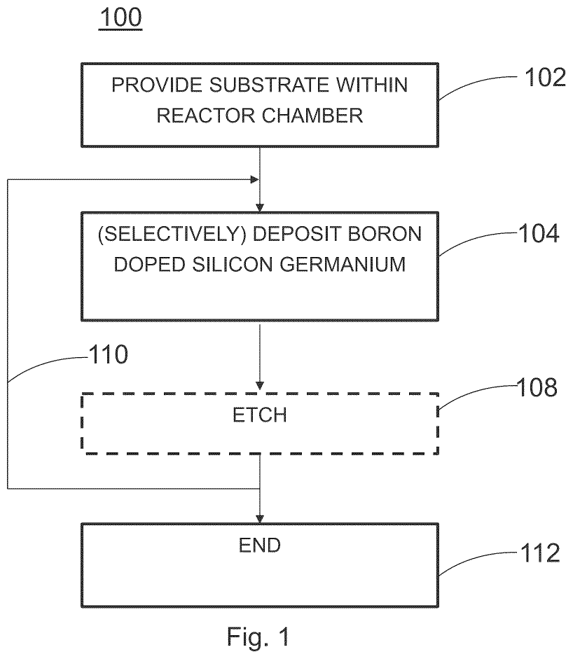

In a first example, reference is made to FIG. 1. FIG. 1 illustrates a (e.g., selective deposition) method (100) in accordance with exemplary embodiments of the disclosure. The method (100) includes the steps of providing a substrate within a reaction chamber (step 102), selectively or non-selectively depositing a boron doped silicon germanium layer (step 104), and optional etching step (step 108), optionally repeating the deposition steps (104) and the etching step (108) (loop 110), and ending (step 112).

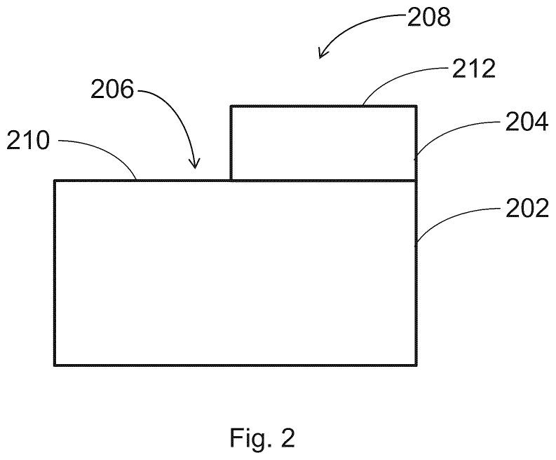

With reference to FIG. 1 and FIG. 2, a substrate (or structure) (200) provided during step (102) can include a first area (206) comprising a first material (e.g., (mono)-crystalline bulk material (202)) and a second area (208) comprising a second material (e.g., non-monocrystalline material (204)). The first material can include a monocrystalline surface (210);

second area (208) can include a non-monocrystalline surface (212), such as a polycrystalline surface or an amorphous surface. The monocrystalline surface (210) may be a monocrystalline silicon surface. Additionally or alternatively, the monocrystalline surface (210) may comprise a monocrystalline silicon germanium surface. Additionally or alternatively, the monocrystalline surface (210) may comprise a boron doped silicon germanium surface. Additionally or alternatively, the monocrystalline surface (210) may comprise a boron doped silicon germanium surface.

The non-monocrystalline surface (212) may include, for example, dielectric materials, such as oxides, oxynitrides, nitrides, oxycarbides, or oxycarbide nitrides, including, for example, silicon oxides, silicon nitrides, silicon oxynitrides, silicon carbides and mixtures thereof, such as SiOC, SiOCN, and SiON.

As a non-limiting example, the reaction chamber used during the step (102) of providing the substrate may comprise a reaction chamber of a chemical vapor deposition system. This notwithstanding, other reaction chambers and alternative chemical vapor deposition systems may also be utilized to perform the embodiments of the present disclosure. The reaction chamber can be a stand-alone reaction chamber or part of a cluster tool.

The substrate providing step (102) can include heating the substrate to a desired deposition temperature within the reaction chamber. In some embodiments of the disclosure, the substrate providing step (102) includes heating the substrate to a temperature of less than approximately 450° C., or even to a temperature of less than approximately 400° C. For example, in some embodiments of the disclosure, heating the substrate to a deposition temperature may comprise heating the substrate to a temperature of at least 380° C. to at most 420° C. The deposition temperature is maintained throughout the step of depositing the boron doped silicon germanium layer (104), and the optional etching step (108).

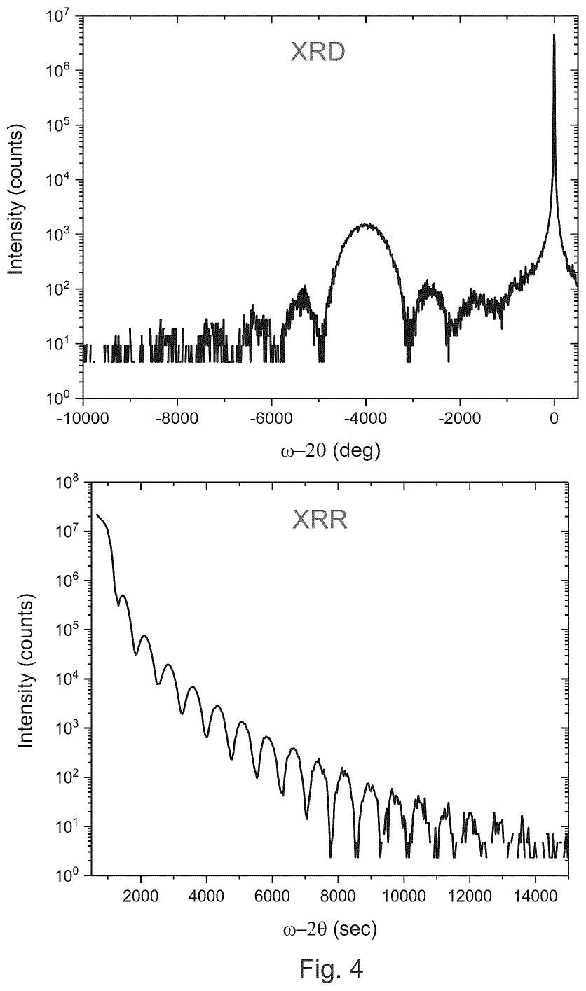

In an exemplary embodiment, the substrate is maintained at a temperature of 400° C., and the reaction chamber is maintained at a pressure of 80 Torr. A stream of disilane (substantially pure) is provided at a flow rate of 30 sccm (standard cubic centimeters per minute), and germane (e.g., as 5 vol. % GeH₄ in N₂ carrier gas) is provided to the reaction chamber at a flow rate of 1650 sccm. 14 sccm B₂H₆ is provided to the reaction chamber diluted in N₂ carrier gas. The N₂ carrier gas is provided at a flow rate of 10 slm (standard liters per minute). In this exemplary process, the precursors and the carrier gas are continually provided to the reaction chamber. Flow rates provided herein are given for 300 mm wafers, but can be readily transferred to other wafer sizes if desired. Such a process yields excellent crystal quality, as evidenced by the XRD (X-ray diffraction measurements) shown in FIG. 4. In addition, haze measurements (6 ppm) and XRR (X-ray reflectivity) measurements (0.3 nm for a 20 nm thick film) indicate very low surface roughness. Thus, excellent boron doped silicon germanium layers can be grown using such a method.

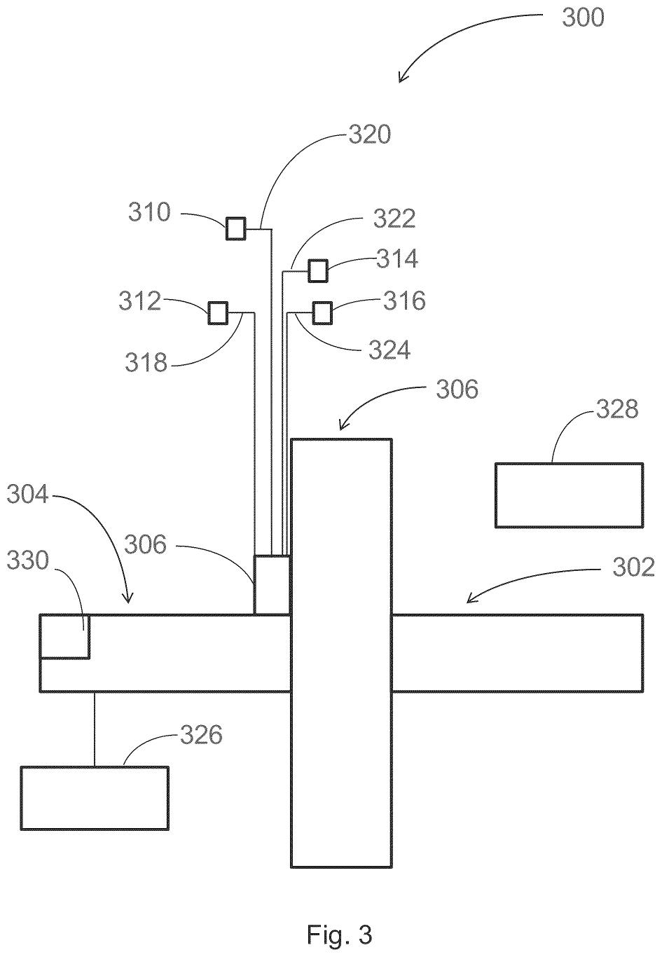

FIG. 3 illustrates a system (300) in accordance with yet additional exemplary embodiments of the disclosure. The system (300) can be used to perform a method as described herein and/or form a structure or device portion as described herein.

In the illustrated example, the system (300) includes an optional substrate handling system (302), one or more reaction chambers (304), a gas injection system (306), and optionally a wall (308) disposed between reaction chamber(s) (304) and substrate handling system (302). The system (300) can also include a first gas source (310), a second gas source (312), a third gas source (314), a fourth gas source (316), an exhaust (326), and a controller (328). At least one of the first through fourth gas source includes a silicon precursor source. The silicon precursor may be disilane. At least one of the first through fourth gas source includes a carrier gas source, for example, a N₂ source. At least one of the first through the fourth gas source includes a germanium precursor source. The germanium precursor may be germane. At least one of the first through fourth gas source includes a boron precursor source. The boron precursor may be diborane.

Although illustrated with four gas sources (310-316), the system (300) can include any suitable number of gas sources. The gas sources (310-316) can each include, for example, precursor gasses, e.g., the silicon, germanium, and boron precursors mentioned herein, including mixtures of such precursors and/or mixtures of one or more precursors with a carrier gas. Additionally, one of the gas sources 310-316 or another gas source can include an etchant, such as an elementary halogen—e.g., chlorine. Gas sources (310)-(316) can be coupled to reaction chamber (304) via lines (318)-(324), which can each include flow controllers, valves, heaters, and the like.

The system (300) can include any suitable number of reaction chambers 304 and substrate handling systems (302). Further, one or more reaction chambers 304 can be or include a cross-flow, cold wall epitaxial reaction chamber.

Vacuum source (320) can include one or more vacuum pumps.

The controller (328) can be configured to perform various functions and/or steps as described herein. For example, the controller (328) can be configured for causing the system (300) to perform a method for epitaxially growing a boron doped silicon germanium layer as described herein.

A controller (328) can include one or more microprocessors, memory elements, and/or switching elements to perform the various functions. Although illustrated as a single unit, the controller (328) can alternatively comprise multiple devices. By way of examples, the controller (328) can be used to control gas flow (e.g., by monitoring flow rates of precursors and/or other gases from the gas sources (310-316) and/or controlling valves, motors, heaters, and the like). Further, when the system (300) includes two or more reaction chambers, the two or more reaction chambers can be coupled to the same/shared controller.

During operation of reactor system (300), substrates, such as semiconductor wafers (not illustrated), are transferred from, e.g., a substrate handling system (302), to a reaction chamber (304). Once substrate(s) are transferred to the reaction chamber (304), one or more gases from gas sources (310-316), such as precursors, dopants, carrier gases, and/or purge gases, are introduced into the reaction chamber (304) via a gas injection system (306). A gas injection system (306) can be used to meter and control gas flow of one or more gases (e.g., from one or more gas sources (310-316)) during substrate processing and to provide desired flows of such gas(es) to multiple sites within the reaction chamber (304).

In an exemplary embodiment, a boron-doped silicon germanium layer is deposited at a temperature of at least 350° C. to at most 450° C., e.g. at a temperature of 400° C., as measured by a pyrometer suspended in the reaction chamber and above the substrate. Disilane is used as a silicon precursor, germane is used as a germanium precursor, and diborane is used as a boron precursor. At a temperature of 400° C., the process can have a nucleation delay of e.g. 5 to 10 nm, when growth on monocrystalline silicon (faster) is compared to growth on a dielectric such as silicon nitride or silicon oxide (slower). Such nucleation delay as such can be used to grow thin boron-doped silicon germanium layers selectively on monocrystalline silicon versus a dielectric. Alternatively, it can be used to grow thicker layers using a deposition-etch process, that may or may not be cyclic, depending on the desired thickness of the deposited layer.

When a deposition-etch process is used, a halogen-containing etchant, such as a chlorine-containing etchant, such as Cl₂ may be advantageously used. Note that the terms etchant and etching gas as used herein can be used interchangeably. A cyclic deposition process may suitably describe alternating growth pulses, and etch pulses. During the growth pulses, a gas mixture comprising disilane, germane, and diborane is provided to the reaction chamber. During the etch pulses, a gas mixture comprising an etchant is provided to the reaction chamber. In some embodiments, the growth pulses and the etch pulses are separated by a purge. During a purge, a substantially inert gas or a mixture of inert gasses can be provided to the reaction chamber, thereby removing reactive species such as precursors and etchants from the reaction chamber.

In advantageous embodiments, an etch pulse lasts less than 130 s, or less than 110 s, or less than 90 s, or less than 70 s, or less than 50 s, or less than 30 s, or less than 20 s, or less than 10 s, or less than 5 s. Such short etch times can advantageously improve surface roughness.

In a further exemplary embodiment, boron-doped silicon germanium is selectively and epitaxially grown on a monocrystalline surface such as monocrystalline silicon. This may be done in a stand-alone deposition, or as part of a process comprising one or more sequences of a deposition and etch. The deposition may be carried out at a temperature of from at least 350° C. to at most 450° C., or at a temperature from at least 380° C. to at most 420° C., e.g. at a temperature of 400° C., as measured by a pyrometer suspended in the reaction chamber, and above the substrate. The process is carried out at a pressure of from at least 40 Torr to at most 160 Torr, or at a pressure of at least 60 Torr to at most 120 Torr, e.g. at a pressure of around 80 Torr. An inert gas such as N2 may be used as a carrier gas, e.g. at a flow rate of at least 5 standard liters per minute (sim) to at most 20 slm, or at least 7.5 slm to at most 15 slm, or around 10 slm. Disilane may be provided to the reaction chamber at a flow rate of 15 to 60 sccm, or at a flow rate of 25 sccm to 35 sccm, e.g. at a flow rate of 30 sccm. Germane may be provided to the reaction chamber at a flow rate of at least 350 sccm to at most 3000 sccm, or a flow rate of at least 800 sccm to at most 3000 sccm, or at a flow rate of at least 1200 sccm to at most 2200 sccm, e.g. at a flow rate of 1700 sccm. Diborane may be provided to the reaction chamber at a flow rate of at least 0.5 sccm to at most 60 sccm, or at a flow rate of at least 5 sccm to at most 20 sccm, or at a flow rate of at least 7.5 sccm to at most 15 sccm, e.g. at a flow rate of around 11 sccm. X-ray diffraction measurements indicated good crystal quality of boron-doped silicon germanium layers deposited using such a process. Also, haze measurements and X-ray reflectivity spectra indicated a low surface roughness. The germanium content can be from at least 10 atomic % to at most 90 atomic %, or from at least 20 atomic % to at most 80 atomic %, or from at least 30 atomic % to at most 70 atomic %, or from at least 40 atomic % to at most 60 atomic %, or about 50 atomic %. Sheet resistance measurements along with thickness measurements indicate that good quality layers of an arbitrary thickness can be grown using a sequence of deposition steps and etch steps. A boron-doped silicon germanium layer grown in accordance with this embodiment is shown in FIG. 5. In particular, FIG. 5 shows a transmission electron micrograph of a substrate comprising bulk monocrystalline silicon (510) on which a silicon oxide layer (520) is grown in some locations. In other locations, the monocrystalline silicon bulk is exposed to the substrate's surface. On top of the silicon oxide layer (520), a silicon nitride layer (530) is grown. Epitaxial and monocrystalline boron-doped silicon germanium (540) was grown on the monocrystalline silicon (510). An amorphous boron-doped silicon germanium (545) was grown on the silicon oxide layer (520) and the silicon nitride layer (530). The silicon oxide layer (520) has a thickness of 8.4 nm. The silicon nitride layer (530) has a thickness of 46.7 nm. The amorphous boron-doped silicon germanium layer has a thickness of 10.3 nm (540). The epitaxial boron-doped silicon germanium layer has a thickness of 22.9 nm. The fact that the amorphous boron-doped silicon germanium layer has a lower thickness than the epitaxial boron-doped silicon germanium layer, and the fact that amorphous boron-doped silicon germanium was found to have a higher etch rate with respect to halogen-containing etchants such as Cl₂, can be used to selectively deposit epitaxial boron-doped silicon germanium on the bulk monocrystalline silicon (510) by means of one or more cycles, each cycle comprising a deposition step followed by an etch step. Without the invention being bound by any particular theory or mode of operation, it is believed that the thickness difference between the epitaxial and monocrystalline boron-doped silicon germanium layer (540) on the one hand and the amorphous boron-doped silicon germanium layer (545) on the other hand, is due to nucleation delay; i.e. boron-doped nuclei are believed to form faster on the monocrystalline silicon bulk (510) than on the silicon oxide layer (520) or the silicon nitride layer (530).

In a further exemplary embodiment, boron-and gallium-doped silicon germanium is selectively and epitaxially grown on a monocrystalline surface such as monocrystalline silicon. This may be done in a stand-alone deposition, or as part of a process comprising one or more sequences of a deposition and etch. The deposition may be carried out at a temperature of from at least 350° C. to at most 450° C., or at a temperature from at least 380° C. to at most 420° C., e.g. at a temperature of 400° C., as measured by a pyrometer suspended in the reaction chamber, and above the substrate. The process is carried out at a pressure of from at least 10 Torr to at most 160 Torr, or at a pressure of from at least 40 Torr to at most 160 Torr, or at a pressure of at least 60 Torr to at most 120 Torr, e.g. at a pressure of around 80 Torr. An inert gas such as N₂ may be used as a carrier gas, e.g. at a flow rate of at least 5 standard liters per minute (slm) to at most 20 slm, or at least 7.5 slm to at most 15 slm, or around 10 slm. Disilane may be provided to the reaction chamber at a flow rate of 15 to 60 sccm, or at a flow rate of 25 sccm to 35 sccm, e.g. at a flow rate of 30 sccm. Germane may be provided to the reaction chamber at a flow rate of at least 350 sccm to at most 3000 sccm, or at a flow rate of at least 800 sccm to at most 3000 sccm, or at a flow rate of at least 1200 sccm to at most 2200 sccm, e.g. at a flow rate of 1700 sccm. Diborane may be provided to the reaction chamber at a flow rate of at least 0.5 sccm to at most 60 sccm, or at a flow rate of at least 5 sccm to at most 20 sccm, or at a flow rate of at least 7.5 sccm to at most 15 sccm, e.g. at a flow rate of around 11 sccm. A gallium alkyl such as tritertiarybutylgallium (TTBGa) may be provided to the reaction chamber at a flow rate of at least 20 sccm to at most 60 sccm, or at a flow rate of at least 30 sccm to at most 50 sccm, e.g. at a flow rate of about 45 sccm. X-ray diffraction measurements indicated good crystal quality. Haze and X-ray reflectivity measurements indicate low surface roughness. The germanium content can be from at least 10 atomic % to at most 90 atomic %, or from at least 20 atomic % to at most 80 atomic %, or from at least 30 atomic % to at most 70 atomic %, or from at least 40 atomic % to at most 60 atomic %, or about 50 atomic %.

In an exemplary etch pulse, chlorine (Cl₂) may be used as an etchant, and may be provided to the reaction chamber at a flow rate of at least 5 sccm to at most 20 sccm, or of at least 7 sccm to at most 15 sccm, or of about 10 sccm. The pressure during the etch pulse may be from at least 20 Torr to at most 80 Torr, or at least 30 Torr to at most 60 Torr, for example around 40 Torr. A Cl₂ flow of 10 sccm at 40 Torr may yield an etch rate of around 8 nm/min.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method for epitaxially growing a boron doped silicon germanium layer comprising:
providing a substrate comprising a monocrystalline surface in a reactor chamber;
performing a deposition cycle, wherein a unit of the deposition cycle consists essentially of:
introducing a gas consisting essentially of a silicon precursor, a germanium precursor, a boron precursor, and a carrier gas into the reactor chamber, thereby epitaxially growing a boron doped silicon germanium layer on the monocrystalline surface, and
a purge step after the step of introducing a gas consisting essentially of a silicon precursor, a germanium precursor, a boron precursor, and a carrier gas into the reactor chamber; and
repeating the deposition cycle a plurality of times until a desired thickness of a boron doped silicon germanium layer is achieved.

2. The method according to claim 1, further comprising performing a pre-clean step prior to the step of performing a deposition cycle, wherein the pre-clean step comprises exposing the surface to NH₄OH, H₂O₂, and H₂O.

3. The method according to claim 1, wherein the substrate is maintained at a temperature to at most 350° C.

4. The method according to claim 1, wherein the reactor chamber is maintained at a pressure of at least 10 Torr to at most 160 Torr.

5. The method according to claim 1 wherein the silicon precursor is provided to the reactor chamber at a flow rate of at least 15 to at most 45 sccm, wherein the germanium precursor is provided to the reactor chamber at a flow rate of at least 350 to at most 2000 sccm, and wherein the boron precursor is provided to the reactor chamber at a flow rate of at least 0.5 sccm to at most 60 sccm.

6. The method according to claim 1, wherein the substrate comprises a first surface and a second surface, wherein the first surface is a monocrystalline surface, wherein the second surface is a dielectric surface; and wherein the boron doped silicon germanium layer is selectively and epitaxially grown on the first surface.

7. The method according to claim 1, wherein the monocrystalline surface comprises a monocrystalline silicon germanium surface.

8. The method according to claim 7, wherein the monocrystalline silicon germanium surface comprises a boron doped silicon germanium surface.

9. The method according to claim 1, wherein the silicon precursor consists of disilane.

10. The method according to claim 1, wherein the germanium precursor consists of germane.

11. The method according to claim 1, wherein the boron precursor consists of diborane.

12. A method for epitaxially growing a boron doped silicon germanium layer comprising:
providing a substrate comprising a monocrystalline surface in a reactor chamber;
performing a deposition cycle, wherein a unit of the deposition cycle comprises:
introducing a gas consisting essentially of a silicon precursor, a germanium precursor, a boron precursor, and a carrier gas into the reactor chamber, thereby epitaxially growing a boron doped silicon germanium layer on the monocrystalline surface, and
a purge step after the step of introducing a gas consisting essentially of a silicon precursor, a germanium precursor, a boron precursor, and a carrier gas into the reactor chamber; and
repeating the deposition cycle a plurality of times until a desired thickness of a boron doped silicon germanium layer is achieved,
wherein the substrate is maintained at a temperature less than about 350° C.

13. The method according to claim 12, wherein the unit of deposition cycle further comprises introducing a gallium precursor into the reactor chamber, thereby epitaxially growing a boron and gallium doped silicon germanium layer on the monocrystalline surface, wherein the gallium precursor comprises a compound selected from the list consisting of trimethylgallium, triethylgallium, tritertiarybutylgallium, Ga(BH₃), GaH₃, and diethylgallium chloride.

14. The method according to claim 12, wherein the substrate comprises a first surface and a second surface, wherein the first surface is a monocrystalline surface, wherein the second surface is a dielectric surface; and wherein the boron doped silicon germanium layer is selectively and epitaxially grown on the first surface.

15. The method according to claim 14, wherein parasitic boron doped silicon germanium is grown on the second surface and wherein the method further comprising the step of:
introducing an etch gas into the reactor chamber, thereby etching the parasitic boron doped silicon germanium grown on the second surface.

16. The method according to claim 15, wherein the etch gas comprises HCl, HBr, or Cl₂.

17. The method according to claim 12, wherein the silicon precursor consists of disilane, wherein the germanium precursor consists of germane, and wherein the boron precursor consists of diborane.

18. The method according to claim 12, further comprising performing a pre-clean step prior to the step of performing a deposition cycle, wherein the pre-clean step comprises exposing the surface to NH₄OH, H₂O₂, and H₂O.

19. A system comprising one or more reaction chambers, a gas injection system, and a controller configured for causing the system to perform a method according to claim 1.

20. A field effect transistor comprising a boron doped silicon germanium layer as a source, drain, and/or channel region wherein the boron doped silicon germanium layer is deposited by means of a method according to claim 1.
